(19) United States
(12) Patent Application Publication
(10) Pub. No.: US 2026/0006955 A1
(43) Pub. Date: Jan. 1, 2026

(54) LIGHT-EMITTING DEVICE AND METHOD FOR MANUFACTURING LIGHT-EMITTING DEVICE

(71) Applicant: NICHIA CORPORATION, Anan-shi (JP)

(72) Inventor: Tamotsu TAKAHASHI, Tokushima-shi (JP)

(73) Assignee: NICHIA CORPORATION, Anan-shi (JP)

(21) Appl. No.: 19/222,570

(22) Filed: May 29, 2025

(30) Foreign Application Priority Data
Jun. 26, 2024 (JP) 2024-103220

(51) Int. Cl. H10H 20/855; H10H 20/01

(52) U.S. Cl. CPC H10H 20/855; H10H 20/021; H10H 20/0363

(57) ABSTRACT

A light-emitting device includes: a light-emitting element; a light-transmissive member disposed on an upper surface and a lateral surface of the light-emitting element; and a light diffusion member disposed on an upper surface of the light-transmissive member. A lateral surface of the light-transmissive member is exposed from the light diffusion member. A distance between an upper surface of the light-emitting element and an upper surface of the light-transmissive member is greater than a distance between a lateral surface of the light-emitting element and a lateral surface of the light-transmissive member. An upper surface of the light-transmissive member includes one or more first protruding portions. The light diffusion member is in contact with a surface of the one or more first protruding portions.

### CROSS-REFERENCE TO RELATED APPLICATION

This application claims priority to Japanese Patent Application No. 2024-103220, filed on Jun. 26, 2024, the disclosure of which is hereby incorporated by reference in its entirety.

### TECHNICAL FIELD

The present disclosure relates to a light-emitting device and a method for manufacturing the light-emitting device.

### BACKGROUND

For example, Japanese Patent Publication No. 2016-154204 discloses a light-emitting device having batwing light distribution characteristics.

### SUMMARY

An object of the present disclosure is to provide a light-emitting device that can increase emission intensity of light emitted in a lateral direction from the light-emitting device, and a method for manufacturing the light-emitting device.

According to an aspect of the present disclosure, a light-emitting device includes a light-emitting element, a light-transmissive member disposed on an upper surface and a lateral surface of the light-emitting element, and a light diffusion member disposed on an upper surface of the light-transmissive member, in which a lateral surface of the light-transmissive member is exposed from the light diffusion member, a distance between an upper surface of the light-emitting element and an upper surface of the light-transmissive member is greater than a distance between a lateral surface of the light-emitting element and a lateral surface of the light-transmissive member, an upper surface of the light-transmissive member has one or more first protruding portions, and the light diffusion member is in contact with a surface of the one or more first protruding portions.

According to an aspect of the present disclosure, a method for manufacturing a light-emitting device includes: providing a first structure including a plurality of light-emitting elements and a first light-transmissive member in a cured state, the first light-transmissive member covering upper surfaces and lateral surfaces of the light-emitting elements; providing a second structure including a second light-transmissive member in an uncured state and a light diffusion member in a cured state, the light diffusion member being disposed on an upper surface of the second light-transmissive member, the upper surface of the second light-transmissive member including one or more first protruding portions, the light diffusion member being in contact with a surface of the one or more first protruding portions; forming a third structure by overlapping the first structure and the second structure so that the first light-transmissive member of the first structure faces the second light-transmissive member of the second structure, and curing the second light-transmissive member; and cutting the third structure into a plurality of light-emitting devices by cutting the third structure at a position where the light-emitting elements are not disposed in a top view.

According to the present disclosure, it is possible to provide a light-emitting device that can increase emission intensity of light emitted in a lateral direction from the light-emitting device, and a method for manufacturing the light-emitting device.

### BRIEF DESCRIPTION OF DRAWINGS

FIG. 1 is a schematic top view of a light-emitting device according to an embodiment.

FIG. 2 is a schematic cross-sectional view taken along the line II-II in FIG. 1.

FIG. 3 is a schematic top view of a light-transmissive member in the light-emitting device according to the embodiment.

FIG. 4 is a schematic cross-sectional view of a light-emitting device according to a first modification of the embodiment.

FIG. 5 is a schematic cross-sectional view of a light-emitting device according to a second modification of the embodiment.

FIG. 6 is a schematic top view of a light-transmissive member according to the second modification of the embodiment.

FIG. 7 is a schematic cross-sectional view of a light-emitting device according to a third modification of the embodiment.

FIG. 8 is a schematic top view of a light-transmissive member according to the third modification of the embodiment.

FIG. 9 is a schematic cross-sectional view of a light-emitting device according to a fourth modification of the embodiment.

FIG. 10 is a schematic cross-sectional view for illustrating a step of the method for manufacturing the light-emitting device according to the embodiment.

FIG. 11 is a schematic cross-sectional view for illustrating a step of the method for manufacturing the light-emitting device according to the embodiment.

FIG. 12 is a schematic cross-sectional view for illustrating a step of the method for manufacturing the light-emitting device according to the embodiment.

FIG. 13 is a schematic cross-sectional view for illustrating a step of the method for manufacturing the light-emitting device according to the embodiment.

FIG. 14 is a schematic cross-sectional view for illustrating a step of the method for manufacturing the light-emitting device according to the embodiment.

FIG. 15 is a schematic cross-sectional view for illustrating a step of the method for manufacturing the light-emitting device according to the embodiment.

FIG. 16 is a schematic cross-sectional view for illustrating a step of the method for manufacturing the light-emitting device according to the embodiment.

FIG. 17 is a schematic cross-sectional view for illustrating a step of the method for manufacturing the light-emitting device according to the embodiment.

FIG. 18 is a schematic cross-sectional view for illustrating a step of the method for manufacturing the light-emitting device according to the embodiment.

FIG. 19 is a schematic cross-sectional view for illustrating a step of the method for manufacturing the light-emitting device according to the embodiment.

FIG. 20 is a schematic cross-sectional view for illustrating a step of the method for manufacturing the light-emitting device according to the embodiment.

FIG. 21A is a schematic cross-sectional view for illustrating a step of the method for manufacturing the light-emitting device according to the embodiment.

FIG. 21B is a schematic cross-sectional view for illustrating a step of the method for manufacturing the light-emitting device according to the embodiment.

FIG. 21C is a schematic cross-sectional view for illustrating a step of the method for manufacturing the light-emitting device according to the embodiment.

FIG. 21D is a schematic cross-sectional view for illustrating a step of the method for manufacturing the light-emitting device according to the embodiment.

### DETAILED DESCRIPTIONS

Light-emitting devices of embodiments are described below with reference to the drawings. Dimensions, materials, shapes, relative arrangements, or the like of constituent members described in the embodiments are not intended to limit the scope of the present invention, unless otherwise specified, and are merely exemplary. The sizes, positional relationship, or the like of members illustrated in each of the drawings may be exaggerated for clarity of description. Furthermore, in the following description, members having the same names and reference signs represent the same or similar members, and detailed description of these members is omitted as appropriate. As a cross-sectional view, an end view illustrating only a cut surface may be illustrated.

In the following description, terms indicating specific directions or positions (for example, “upper”, “lower”, and other terms including those terms) may be used. However, these terms are used merely for making it easy to understand relative directions or positions in the referenced drawing. As long as the relative direction or position is the same as that described in the referenced drawing using the term such as “upper,” “upward,” “lower,” “downward,” or the like, in drawings other than the drawings of the present disclosure, actual products, and the like, components need not be oriented in the same manner as that in the referenced drawing. On the assumption that there are two members, the positional relationship expressed as “on,” “above,” “upper,” “below,” or “lower” in the present specification may include a case in which the two members are in contact with each other and a case in which the two members are not in contact with each other and one of the two members is located above or below the other member.

In the following drawings, directions may be indicated by an X axis, a Y axis, and a Z axis that are orthogonal to each other. For example, in the present specification, the direction of the X axis is referred to as a first direction X, the direction of the Y axis is referred to as a second direction Y, and the direction of the Z axis is referred to as a third direction Z. Further, the arrow direction (plus direction) of the Z axis is relatively upward, and the opposite direction (minus direction) to the arrow direction is relatively downward. The first direction X side or the second direction Y side may be referred to as a “lateral side.” The expressions “in a top view” and “top view” refer to a view of an object from the arrow direction of the Z axis.

In the present specification, the expression “unreacted state” of resin represents a state in which the resin is not heated and the curing reaction has not started yet. In addition, the expression “uncured state” of the resin represents a state of Stage A or Stage B in which the resin is heated, and the curing reaction occurs. In addition, the expression “cured state” of the resin represents a state of Stage C in which the resin is completely cured.

Stage A, Stage B, and Stage C representing the cured state of the resin are defined as follows according to the JISK6800 standard.

Stage A: Initial state of a thermosetting resin forming reaction. The resin in this state is still soluble in a certain kind of solvent and melts when heated.

Stage B: Intermediate cured state of the thermosetting resin. The resin in this state softens when heated and swells when brought into contact with a certain kind of solvent, but does not completely melt or dissolve.

Stage C: Final state of the curing reaction of the thermosetting resin. The resin in this state is insoluble and infusible.

### Light-Emitting Device

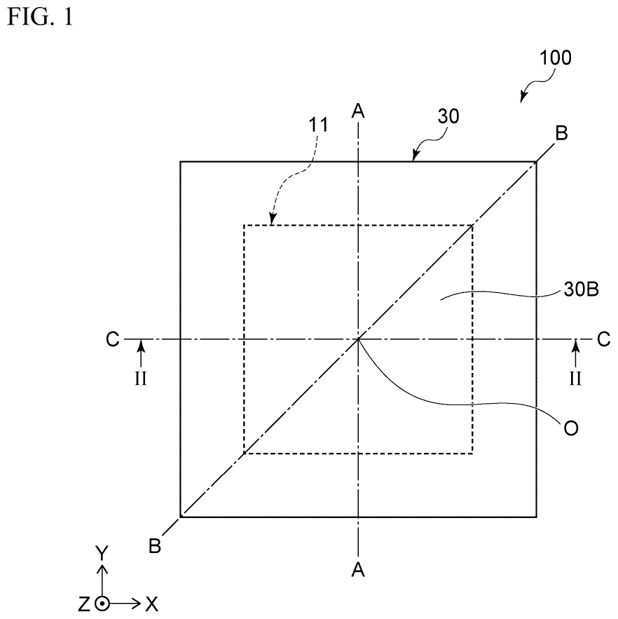

A light-emitting device 100 of the embodiment is described below with reference to FIGS. 1 to 3.

In the example illustrated in FIG. 1, the shape of the light-emitting device 100 in a top view is a rectangle having two sides extending in the first direction X and two sides extending in the second direction Y. For example, the length of each side of the light-emitting device 100 is in a range from 0.8 mm to 2.5 mm. For example, the thickness of the light-emitting device 100 is in a range from 0.8 mm to 3.0 mm.

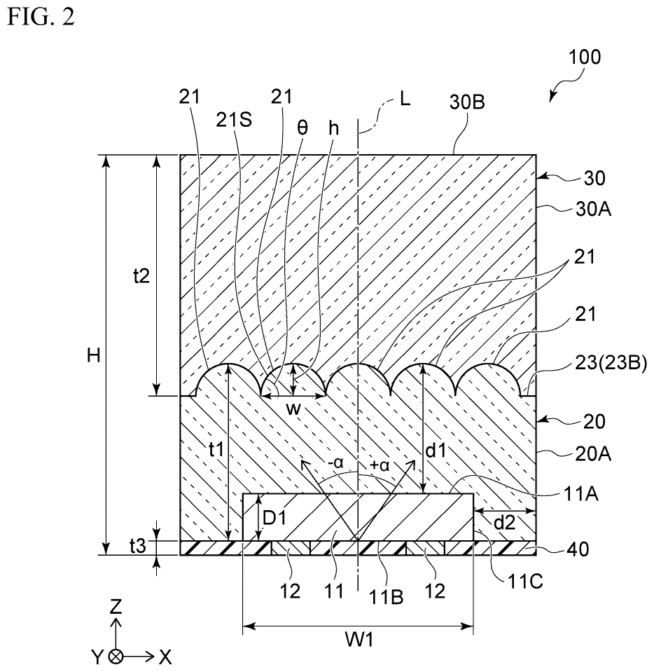

FIG. 2 is a schematic cross-sectional view taken along the line II-II in FIG. 1. The light-emitting device 100 includes a light-emitting element 11, a light-transmissive member 20, and a light diffusion member 30.

### Light-Emitting Element

In the example illustrated in FIG. 1, the shape of the light-emitting element 11 in a top view is rectangular. In a top view, each side of the light-emitting element 11 is parallel to a corresponding one of the sides of the light-emitting device 100. For example, the length of each side of the light-emitting element 11 is in a range from 640 μm to 1300 μm.

The light-emitting element 11 has an upper surface 11A, a lower surface 11B, and a lateral surface 11C as illustrated in FIG. 2.

The light-emitting element 11 is, for example, a light-emitting diode (LED) element. The light-emitting element 11 includes a semiconductor structure. The semiconductor structure includes an n-side semiconductor layer, a p-side semiconductor layer, and a light-emitting layer located between the n-side semiconductor layer and the p-side semiconductor layer. The n-side semiconductor layer contains n-type impurities. The p-side semiconductor layer contains p-type impurities. The light-emitting layer includes a double heterojunction, a single quantum well (SQW), or a multi quantum well (MQW) including a plurality of well layers. Each of the n-side semiconductor layer, the light-emitting layer, and the p-side semiconductor layer is, for example, a semiconductor layer formed of a nitride semiconductor. The nitride semiconductor includes a semiconductor having all compositions in which, in a chemical formula of InₓAl_{y}Ga_{1-x-y}N (0≤x, 0≤y, and x+y≤1), composition ratios x and y are changed within their respective ranges. The light emission peak wavelength of the light-emitting layer can be selected as appropriate according to the purpose. The light-emitting layer is configured, for example, to be able to emit visible light or ultraviolet light.

In a case in which the structure including the n-side semiconductor layer, the p-side semiconductor layer, and the light-emitting layer is one layered body, the semiconductor structure can include a plurality of layered bodies. In this case, the plurality of layered bodies overlap each other in the third direction Z. In the light-emitting layer included in each of the plurality of layered bodies, the semiconductor structure may include well layers having different light emission peak wavelengths or well layers having the same light emission peak wavelength. The expression “having the same light emission peak wavelength” includes a case in which there is a variation of several nanometers. A combination of light emission peak wavelengths between a plurality of active layers can be selected as appropriate. For example, when the semiconductor structure includes two layered bodies, the combinations of light emitted from the light-emitting layers of the layered bodies include a combination of blue light and blue light, a combination of green light and green light, a combination of red light and red light, a combination of ultraviolet light and ultraviolet light, a combination of blue light and ultraviolet light, a combination of blue light and green light, a combination of blue light and red light, or a combination of green light and red light. For example, when the semiconductor structure includes three layered bodies, the combinations of light emitted from the light-emitting layers of the layered bodies include a combination of blue light, green light, and red light.

The light-emitting element 11 further includes element electrodes. The element electrodes are located near the lower surface 11B of the light-emitting element 11 and include an n-side element electrode electrically connected to the n-side semiconductor layer, and a p-side element electrode electrically connected to the p-side semiconductor layer. The light-emitting element 11 may or may not include an element substrate of sapphire or the like on the upper surface side of the semiconductor structure.

### Light-Transmissive Member

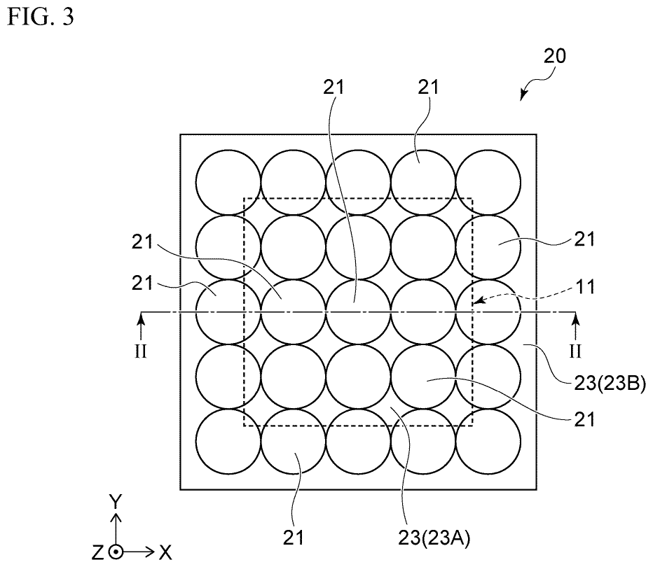

FIG. 3 is a schematic top view of an upper surface of the light-transmissive member 20 in the light-emitting device 100 according to the embodiment. The cross section of the light-transmissive member 20 illustrated in FIG. 2 is a cross section taken along the line II-II in FIG. 3.

The light-transmissive member 20 is disposed on the upper surface 11A and the lateral surface 11C of the light-emitting element 11. Light emitted by the light-emitting element 11 enters the light-transmissive member 20 from the upper surface 11A and the lateral surface 11C of the light-emitting element 11.

The light-transmissive member 20 includes a first base material and a wavelength conversion material that converts the wavelength of light emitted by the light-emitting element 11. The first base material is transmissive to light emitted by the light-emitting element 11. As the first base material, for example, resin having high heat resistance, high weather resistance, and high light resistance can be used. As the resin of the first base material, a silicone resin, an epoxy resin, a urea resin, a phenol resin, an acrylic resin, a urethane resin, or a fluororesin, or a thermosetting resin including two or more types of the resin can be used.

As the wavelength conversion material, a phosphor can be used, for example. Examples of the phosphor that can be used include an yttrium aluminum garnet phosphor (for example, Y₃(Al,Ga)₅O₁₂:Ce), a lutetium aluminum garnet phosphor (for example, Lu₃(Al,Ga)₅O₁₂:Ce), a terbium aluminum garnet phosphor (for example, Tb₃(Al,Ga)₅O₁₂:Ce), a CCA phosphor (for example, Ca₁₀(PO₄)₆Cl₂:Eu), an SAE phosphor (for example, Sr₄Al₁₄O₂₅:Eu), a chlorosilicate phosphor (for example, CasMgSi₄O₁₆Cl₂:Eu), a nitride phosphor such as a β-sialon phosphor (for example, (Si,Al)₃(O,N)₄:Eu), an α-sialon phosphor (for example, Ca(Si,Al)₁₂(O,N)₁₆:Eu), an SLA phosphor (for example, SrLiAl₃N₄:Eu), a CASN phosphor (for example, CaAlSiN₃:Eu), or an SCASN phosphor (for example, (Sr,Ca)AlSiN₃:Eu), a fluoride phosphor such as a KSF phosphor (for example, K₂SiF₆:Mn), a KSAF phosphor (for example, K₂(Si,Al)F₆:Mn), or an MGF phosphor (for example, 3.5MgO·0.5MgF₂·GeO₂:Mn), a phosphor having a perovskite structure (for example, CsPb(F,Cl,Br,I)₃), and a quantum dot phosphor (for example, CdSe, InP, AgInS₂, or AgInSe₂).

As the wavelength conversion material included in the light-transmissive member 20, one type or a plurality of types of wavelength conversion materials may be used. When the plurality of types of wavelength conversion materials are used, the plurality of types of wavelength conversion materials may be contained in the entire light-transmissive member 20, or the light-transmissive member 20 may be divided into a plurality of layers and the plurality of types of wavelength conversion materials may be contained in the respective layers. For example, when two kinds of wavelength conversion materials are contained in two layers, the light-transmissive member 20 can include a first layer disposed on the lateral surface 11C and the upper surface 11A of the light-emitting element 11 and containing a first wavelength conversion material, and a second layer disposed on the outer lateral surface and the upper surface of the first layer and containing a second wavelength conversion material.

The light-transmissive member 20 may or does not have to contain a wavelength conversion material.

In the example illustrated in FIG. 3, the shape of the light-transmissive member 20 in a top view is rectangular, and the light-transmissive member 20 has four lateral surfaces 20A. In the example illustrated in FIG. 2, all of the four lateral surfaces 20A of the light-transmissive member 20 are exposed from the light diffusion member 30 without being covered with the light diffusion member 30.

The upper surface of the light-transmissive member 20 includes one or more first protruding portions 21. In the example illustrated in FIGS. 2 and 3, the upper surface of the light-transmissive member 20 includes a plurality of first protruding portions 21. In the example illustrated in FIG. 3, the plurality of first protruding portions 21 are regularly arranged so that the lengths between the centers of adjacent first protruding portions 21 are equal in the first direction X and the second direction Y.

For example, the surface of the first protruding portion 21 is a curved surface. In the example illustrated in FIGS. 2 and 3, the shape of the first protruding portion 21 in a cross-sectional view is hemispherical, and the shape of the first protruding portion 21 in a top view is circular. The upper surface of the light-transmissive member 20 includes flat portions 23 parallel to the upper surface 11A of the light-emitting element 11 in a region other than the first protruding portion 21. The flat portions 23 include an outer flat portion 23B surrounding first protruding portions 21 of the plurality of first protruding portions 21, which are arranged at the outermost periphery in a top view. In addition, the flat portions 23 includes an inner flat portion 23A located between the first protruding portions 21 adjacent to each other in a direction inclined with respect to the first direction X and the second direction Y. In the example illustrated in FIGS. 2 and 3, the inner flat portion 23A is not provided between the first protruding portions 21 adjacent to each other in the first direction X. In addition, the inner flat portion 23A is not provided between the first protruding portions 21 adjacent to each other in the second direction Y. However, there is no limitation thereto, and the inner flat portion 23A may be provided between the first protruding portions 21 adjacent to each other in the first direction X. In addition, the inner flat portion 23A may be provided between the first protruding portions 21 adjacent to each other in the second direction Y.

In a top view, the proportion of the area occupied by the first protruding portions 21 in the region of the upper surface of the light-transmissive member 20 that overlaps the upper surface 11A of the light-emitting element 11 is preferably in a range from 50% to 100%. Accordingly, it is possible to increase the amount of light that is emitted upward from the light-emitting element 11 and then refracted toward a lateral surface 30A of the light diffusion member 30 by the first protruding portions 2.

### Light Diffusion Member

The light diffusion member 30 is disposed on the upper surface of the light-transmissive member 20. In the example illustrated in FIG. 1, the shape of the light diffusion member 30 in a top view is rectangular. The light diffusion member 30 has four lateral surfaces 30A continuous with the four lateral surfaces 20A of the light-transmissive member 20 in the third direction Z, respectively. In the example illustrated in FIG. 2, an upper surface 30B of the light diffusion member 30 is a flat surface.

The light diffusion member 30 is in contact with the surface of the first protruding portions 21 of the light-transmissive member 20. The light diffusion member 30 is in contact with the surface of the flat portion 23 of the light-transmissive member 20. The interface between the light-transmissive member 20 and the light diffusion member 30 is located on the surface of the first protruding portions 21 and the surface of the flat portion 23.

The light diffusion member 30 includes a second base material and a first light reflective material. The second base material is transmissive to light emitted by the light-emitting element 11 and light that has been subjected to wavelength conversion by the wavelength conversion material of the light-transmissive member 20. For example, the second base material can be the same material as the resin used for the first base material of the light-transmissive member 20.

As a first light reflective material included in the light diffusion member 30, for example, particles of silicon oxide, titanium oxide, aluminum oxide, or barium titanate can be used. The light diffusion member 30 may include a filler for adjusting viscosity in addition to the light reflective material.

Of light emitted by the light-emitting element 11, light that has not been subjected to wavelength conversion by the wavelength conversion material, and light that has been subjected to wavelength conversion by the wavelength conversion material are incident on the light diffusion member 30 from the upper surface of the light-transmissive member 20. The light diffusion member 30 diffuses light incident from the upper surface of the light-transmissive member 20.

The refractive index of the second base material of the light diffusion member 30 is higher than the refractive index of the first base material of the light-transmissive member 20. This can reduce reflection of light incident on the light diffusion member 30 from the light-transmissive member 20 at the interface between the first base material and the second base material, and thus can increase light extraction efficiency of the light-emitting device 100.

For example, a phenyl silicone resin can be used as the second base material of the light diffusion member 30. In this case, the first light reflective material is preferably silicon oxide. The refractive index difference between the phenyl silicone resin and the silicon oxide can be reduced compared to the refractive index difference between the phenyl silicone resin and the titanium oxide. The refractive index difference between the second base material and the first light reflective material in the light diffusion member 30 is reduced, so that return light that is reflected at an interface between the second base material and the first light reflective material and returns into the light-transmissive member 20 can be reduced.

A light emission surface of the light-emitting device 100 includes the upper surface 30B of the light diffusion member 30, the lateral surface 30A of the light diffusion member 30, and the lateral surface 20A of the light-transmissive member 20. From the upper surface 30B of the light diffusion member 30, the lateral surface 30A of the light diffusion member 30, and the lateral surface 20A of the light-transmissive member 20, light is emitted which is the mixed light of light emitted by the light-emitting element 11 without being subjected to wavelength conversion by the wavelength conversion material, and light emitted by the light-emitting element 11 subjected to wavelength conversion by the wavelength conversion material.

In the example illustrated in FIG. 2, the lateral surfaces of the light-emitting device 100 (i.e., the lateral surface 20A of the light-transmissive member 20 and the lateral surface 30A of the light diffusion member 30) are surfaces perpendicular to the upper surface of the light-emitting device 100 (i.e., the upper surface 30B of the light diffusion member 30). However, there is no limitation thereto, and the lateral surfaces of the light-emitting device 100 may be a surface inclined with respect to the upper surface of the light-emitting device 100. When the lateral surface of the light-emitting device 100 is inclined with respect to the upper surface of the light-emitting device 100, for example, the lateral surface of the light-emitting device 100 can be inclined such that the width of the light-emitting device 100 in the first direction X decreases from the lower end to the upper end of the lateral surface of the light-emitting device 100.

In the example illustrated in FIG. 2, there is no step between the lateral surface 20A of the light-transmissive member 20 and the lateral surface 30A of the light diffusion member 30 in the third direction Z, and the lateral surface 20A of the light-transmissive member 20 and the lateral surface 30A of the light diffusion member 30 are continuous on the same plane.

The light-emitting device 100 according to the embodiment may further include or may not include the configuration described below.

### Electrode

In the example illustrated in FIG. 2, two electrodes 12 are arranged on the lower surface of the light-emitting element 11. The electrodes 12 are electrically connected to the element electrode of the light-emitting element 11 described above. One of the two electrodes 12 functions as an anode electrode and the other functions as a cathode electrode. The light-emitting element 11 is electrically connected to the wiring substrate via the electrodes 12. As a material of the electrodes 12, for example, Cu, Ni, Ru, Au, Ag, Pt, Fe, or Su can be used. The electrode 12 can include a first portion electrically connected to the element electrode and surrounded by a light reflective member 40 described later, and a second portion electrically connected to the first portion and disposed at the lower portion of the light reflective member 40. When the light-emitting device 100 includes the electrodes 12, the electrodes 12 function as an external connection terminal of the light-emitting device 100. When the light-emitting device 100 does not include the electrodes 12, the element electrode of the light-emitting element 11 functions as an external connection terminal of the light-emitting device 100.

### Light Reflective Member

The light reflective member 40 is disposed on the lower surface 11B of the light-emitting element 11 and the lower surface of the light-transmissive member 20. The light reflective member 40 covers a lateral surface of the electrode 12. A lower surface of the electrode 12 is exposed from the light reflective member 40.

The light reflective member 40 has reflectivity to light emitted by the light-emitting element 11 without being subjected to wavelength conversion by the wavelength conversion material, and to light emitted by the light-emitting element 11 subjected to wavelength conversion by the wavelength conversion material. The light directed downward from the light-emitting element 11 and the light-transmissive member 20 is reflected off the light reflective member 40 toward an upward direction from the light reflective member 40. This can increase the amount of light from the light emission surfaces of the light-emitting device 100 (the upper surface 30B of the light diffusion member 30, the lateral surface 30A of the light diffusion member 30, and the lateral surface 20A of the light-transmissive member 20).

The light reflective member 40 includes a third base material and a second light reflective material. As the third base material, for example, the resin referred to as the first base material of the light-transmissive member 20 can be used. As the second light reflective material, for example, a material referred to as the first light reflective material of the light diffusion member 30 can be used. The second light reflective material may be the same material as or different from the first light reflective material. The concentration of the second light reflective material in the light reflective member 40 is higher than the concentration of the first light reflective material in the light diffusion member 30. For example, the concentration of the second light reflective material in the light reflective member 40 is 60 wt. %, and the concentration of the first light reflective material in the light diffusion member 30 is 4.72 wt. %.

A thickness t3 of the light reflective member 40 is less than a thickness t1 of the light-transmissive member 20 and a thickness t2 of the light diffusion member 30. The thickness t3 of the light reflective member 40 is, for example, in a range from 0.015 mm to 0.06 mm.

The light-emitting device 100 can have light distribution characteristics (so-called batwing light distribution characteristics) that light has a first luminous intensity peak in a range of the light distribution angle from 0° to −90° (excluding 0° and)−90°. The first luminous intensity peak is higher than the luminous intensity at the light distribution angle illustrated in FIG. 2 of 0°. The light distribution characteristics (so-called batwing light distribution characteristics) of the light-emitting device 100 can also has a second luminous intensity peak in a range of the light distribution angle from 0° to 90° (excluding 0° and) 90°. The second luminous intensity peak is higher than the luminous intensity at the light distribution angle illustrated in FIG. 2 of 0°. As illustrated in FIG. 2, the light distribution angle refers to an angle α representing a spread of light emitted from the light-emitting element 11 with respect to an optical axis L. As illustrated in the example of FIG. 2, the light distribution angle α of light inclined in the first direction X (the arrow direction of the X axis) with respect to the optical axis L is represented as +α°, and the light distribution angle α of light inclined in a direction opposite to the first direction X (the arrow direction of the X axis) with respect to the optical axis L is represented as −α°. Here, the optical axis L indicates a normal line passing through the center of the upper surface 11A of the light-emitting element 11.

The refractive index of the second base material of the light diffusion member 30 is higher than the refractive index of the first base material of the light-transmissive member 20. Therefore, when the first protruding portions 21 are disposed on the upper surface of the light-transmissive member 20, which is the interface between the light-transmissive member 20 and the light diffusion member 30, the light-emitting device 100 can refract the light emitted by the light-emitting elements 11 in a wide-angle direction with respect to the optical axis L at the interface between the light-transmissive member 20 and the light diffusion member 30, as compared with a light-emitting device in which the interface between the light-transmissive member 20 and the light diffusion member 30 is a flat surface (hereinafter, referred to as “light-emitting device of Reference Example 1” in some cases). As such, the light-emitting device 100 can increase the amount of light emitted from the lateral surface 30A of the light diffusion member 30, and can increase the emission intensity of light emitted in the lateral direction from the light-emitting device 100 as compared with the light-emitting device of Reference Example 1. As a result, in the light distribution characteristics of the light-emitting device 100, the first luminous intensity peak is shifted to the −90° side and the second luminous intensity peak is shifted to the 90° side as compared with the light-emitting device of Reference Example 1.

The light-emitting device 100 is used as, for example, a light source of a lighting fixture, so that brightness unevenness on a light-emitting surface of the lighting fixture can be reduced even when the distance from the light-emitting device 100 to the light-emitting surface of the lighting fixture is short as a result of a reduction in the thickness of the lighting fixture. Furthermore, a person viewing the light-emitting surface of the lighting fixture is less likely to feel that the light-emitting device 100 is too bright at certain points. As a result, the thickness of the lighting fixture including the light-emitting device 100 can be reduced, and the weight of the lighting fixture can be reduced as the lighting fixture is made thinner.

In addition, the light-emitting device 100 in which the upper surface of the light-transmissive member 20 has the first protruding portions 21 can increase the emission intensity of light emitted in the lateral direction from the light-emitting device 100 as compared with a light-emitting device in which the upper surface of the light-transmissive member 20 does not include the first protruding portions 21 and the upper surface 30B of the light diffusion member 30 includes protruding portions (a light-emitting device having a configuration in which the upper surface of the light-transmissive member 20 illustrated in FIG. 3 is replaced with the upper surface of the light diffusion member 30). This is because light from the light-emitting element 11 can be refracted to the lateral side of the light-emitting device 100 at the upper surface of the light-transmissive member 20 located closer to the light-emitting element 11 in the third direction Z relative to the upper surface 30B of the light diffusion member 30, and the amount of light emitted from the lateral surface of the light-emitting device 100 can be increased.

In addition, in the light-emitting device 100 according to the embodiment, the lateral surface 20A of the light-transmissive member 20 is not covered with the light diffusion member 30 and is exposed from the light diffusion member 30. On the other hand, a light-emitting device having a configuration in which the lateral surface of the light-transmissive member 20 is covered with the light diffusion member 30 is conceivable. When the light-emitting device having a configuration in which the lateral surface of the light-transmissive member 20 is covered with the light diffusion member 30, has the same outer size as the light-emitting device 30 according to the embodiment, because a distance between a lateral surface of the light-emitting element 11 and the lateral surface 20A of the light-transmissive member 20 is shorter, the degree of margin for the misalignment of the light-emitting element 11 with respect to the light-transmissive member 20 is reduced as compared with the light-emitting device 100. In the light-emitting device 100 according to the embodiment, a distance d2 between the lateral surface of the light-emitting element 11 and the lateral surface 20A of the light-transmissive member 20 can be increased and chromaticity unevenness of the light-emitting device 100 due to misalignment of the light-emitting element 11 can be reduced as compared with the light-emitting device having the configuration in which the lateral surface of the light-transmissive member 20 is covered with the light diffusion member 30. According to the present embodiment, the light-emitting device 100 having a desired chromaticity distribution can be provided.

According to the present embodiment, as illustrated in the example of FIG. 2, a distance d1 between the upper surface 11A of the light-emitting element 11 and the upper surface of the light-transmissive member 20 is greater than the distance d2 between the lateral surface 11C of the light-emitting element 11 and the lateral surface 20A of the light-transmissive member 20. The distance d1 represents the maximum distance between the upper surface 11A of the light-emitting element 11 and the upper surface of the light-transmissive member 20 in the third direction Z. The distance d2 represents the maximum distance between the lateral surface 11C of the light-emitting element 11 and the lateral surface 20A of the light-transmissive member 20 in the first direction X or the second direction Y. The distance d1 is, for example, in a range from 220 μm to 640 μm. The distance d2 is, for example, in a range from 170 μm to 360 μm.

Light emitted from the light-emitting element 11 includes light emitted from and directed directly above the upper surface 11A of the light-emitting element 11 and light emitted from the lateral surface 11C of the light-emitting element 11. The amount of light emitted from and directed directly above the upper surface 11A of the light-emitting element 11 is larger than the amount of light emitted from the lateral surface 11C of the light-emitting element 11. The light emitted from and directed directly above the upper surface 11A of the light-emitting element 11 is greater than the light emitted from the lateral surface 11C of the light-emitting element 11. In other words, the light emitted from the lateral surface 11C of the light-emitting element 11 is less than the light emitted from and directed directly above the upper surface 11A of the light-emitting element 11. The distance d1 is set greater than the distance d2, so that the amount of the wavelength conversion material contributing to wavelength conversion by the light emitted from and directed directly above the upper surface 11A of the light-emitting element 11 is relatively large. Also, the amount of the wavelength conversion material contributing to wavelength conversion by the light emitted from the lateral surface 11C of the light-emitting element 11 is relatively small. As a result, it is possible to reduce the variation in the ratio between the light subjected to wavelength conversion and the light without being subjected to wavelength conversion both directly above and on the lateral side of the light-emitting element 11. It is thus possible to easily reduce the variation in chromaticity directly above and on the lateral side of the light-emitting device 100.

According to the present embodiment, as illustrated in the example of FIG. 2, the thickness t2 of the light diffusion member 30 is greater than the thickness t1 of the light-transmissive member 20. Accordingly, it is possible to increase the amount of light emitted from the lateral surface 30A of the light diffusion member 30 which is a mixture of the light without being subjected to the wavelength conversion and the light subjected to the wavelength conversion. It is thus possible to increase the emission intensity of light emitted in the lateral direction from the light-emitting device 100. Furthermore, it is possible to obtain the light-emitting device 100 in which chromaticity unevenness is reduced.

The thickness t1 of the light-transmissive member 20 represents the maximum thickness along the third direction Z between the lower surface and the upper surface of the light-transmissive member 20. The thickness t2 of the light diffusion member 30 represents the maximum thickness along the third direction Z between the lower surface and the upper surface of the light diffusion member 30. The thickness t1 of the light-transmissive member 20 is, for example, in a range from 0.36 mm to 0.91 mm. The thickness t2 of the light diffusion member 30 is, for example, in a range from 0.63 mm to 1.46 mm. For example, the thickness t2 of the light diffusion member 30 is in a range from 1.1 times to 2.0 times of the thickness t1 of the light-transmissive member 20.

According to the present embodiment, the total area of the four lateral surfaces 20A of the light-transmissive member 20 and the four lateral surfaces 30A of the light diffusion member 30 is greater than the area of the upper surface 30B of the light diffusion member 30. Thus, the amount of light emitted from all lateral surfaces of the light-emitting device 100 can be increased compared to the amount of light emitted from the upper surface thereof, so that the emission intensity of light emitted in the lateral direction from the light-emitting device 100 can be increased.

In addition, according to the present embodiment, the ratio of the overall thickness H of the light-emitting device 100 to one side of the light-emitting device 100 in a top view can be set in a range from 1.01 to 1.24. The overall thickness H of the light-emitting device 100 illustrated in FIG. 2 is calculated by subtracting a maximum height h of the first protruding portion 21 described later from the sum of the thickness t1 of the light-transmissive member 20, the thickness t2 of the light diffusion member 30, and the thickness t3 of the light reflective member 40.

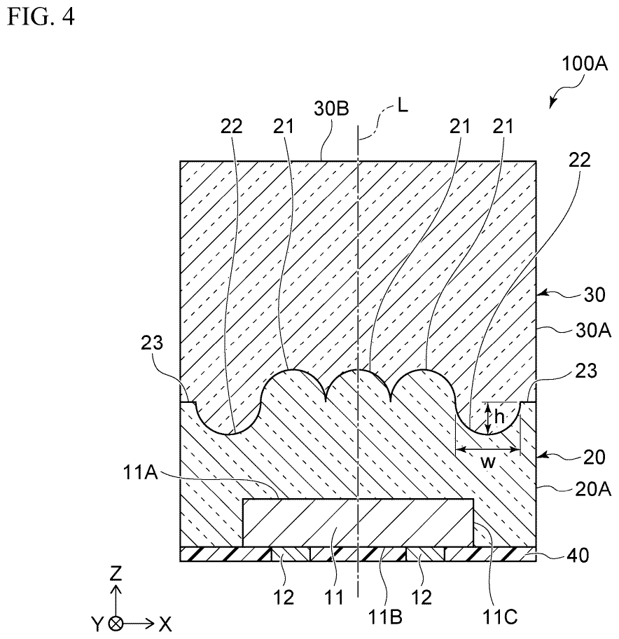

As in a light-emitting device 100A according to a first modification of the embodiment illustrated in FIG. 4, the upper surface of the light-transmissive member 20 can include the first protruding portions 21 and first recessed portion(s) 22. For example, the first recessed portion(s) 22 are located outward of the first protruding portions 21, and are disposed so as to surround the first protruding portions 21 in a top view. The light from the light-emitting element 11 is refracted by the first protruding portions 21 toward the wide-angle side with respect to the optical axis L (i.e., toward the lateral side of the light-emitting device 100A), and is refracted by the first recessed portions 22 toward the low-angle side with respect to the optical axis L (i.e., toward the upper side of the light-emitting device 100A). As a result, the emission intensity of light at a desired light distribution angle can be increased.

When the upper surface of the light-transmissive member 20 includes the flat portion 23, the surface of the first protruding portion 21 is located above the flat portion 23 in the third direction Z. The surface of the first recessed portion 22 is located below the flat portion 23 in the third direction Z. On the other hand, when the upper surface of the light-transmissive member 20 does not include the flat portion 23, the uppermost end of the first protruding portion 21 is located above a line connecting opposite ends of the interface between the light-transmissive member 20 and the light diffusion member 30 in a cross-sectional view. The lowermost end of the first recessed portion 22 is located below a line connecting opposite ends of the interface between the light-transmissive member 20 and the light diffusion member 30 in a cross-sectional view.

The upper surface of the light-transmissive member 20 is not limited to including the plurality of first protruding portions 21, and the upper surface of the light-transmissive member 20 may include one first protruding portion 21. The one first protruding portion 21 can be disposed in a central portion that is a portion including at least the center of the upper surface of the light-transmissive member 20 in a top view.

It is preferable that the center of the first protruding portion 21 and the center of the light-emitting element 11 overlap each other in a top view. In this way, deviation in the light distribution characteristics can be reduced. Here, the deviation of the light distribution characteristics refers to a decrease in symmetry between the light distribution characteristics on the first direction X side (the arrow direction side of the X axis) with respect to the optical axis L and the light distribution characteristics on the direction side opposite to the first direction X with respect to the optical axis L.

In a cross-sectional view, a maximum width w of the first protruding portion 21 (or the first recessed portion 22) is, for example, in a range from 1/20 to ⅕ of the width of the light-transmissive member 20.

The maximum height h of the first protruding portion 21 (or the first recessed portion 22) is, for example, in a range from 0.5 times to 2 times of the maximum width w of the first protruding portion 21 (or the first recessed portion 22). The maximum height h of the first protruding portion 21 (or the first recessed portion 22) corresponds to the distance between the upper end and the lower end of the first protruding portion 21 (or the first recessed portion 22) in the third direction Z.

In a cross-sectional view, an inclination angle θ of an oblique line 21S between the upper end and the lower end of the first protruding portion 21 (in a case in which the oblique line 21S is a curved line, the inclination angle θ of the tangent line being in contact with the oblique line 21S) is considered. The inclination angle θ is an inclination angle with respect to a line connecting opposite ends of the interface between the light-transmissive member 20 and the light diffusion member 30 in a cross-sectional view. When the inclination angle θ is in a range from 45° to 76°, h is preferably in a range from 0.5 times to 2 times of w. When the inclination angle θ is in a range from 50° to 70°, h is preferably in a range from 0.6 times to 1.3 times of w.

The inclination angle θ is preferably not less than 45°. Accordingly, it is possible to increase the amount of light that is refracted on the surface of the first protruding portion 21 and travels toward the lateral surface 30A of the light diffusion member 30.

In the example illustrated in FIGS. 2 and 3, the surface of the first protruding portion 21 is a curved surface. Thus, light from the light-emitting element 11 is refracted in all directions in a top view by the first protruding portion 21. Accordingly, in the light distribution characteristics of the light-emitting device 100, the first luminous intensity peak and the second luminous intensity peak of the light distribution characteristics in each direction can be shifted to the −90° side, and to the 90° side, respectively, in the entire circumferential direction in a top view, as compared with the light distribution characteristics of the light-emitting device of Reference Example 1.

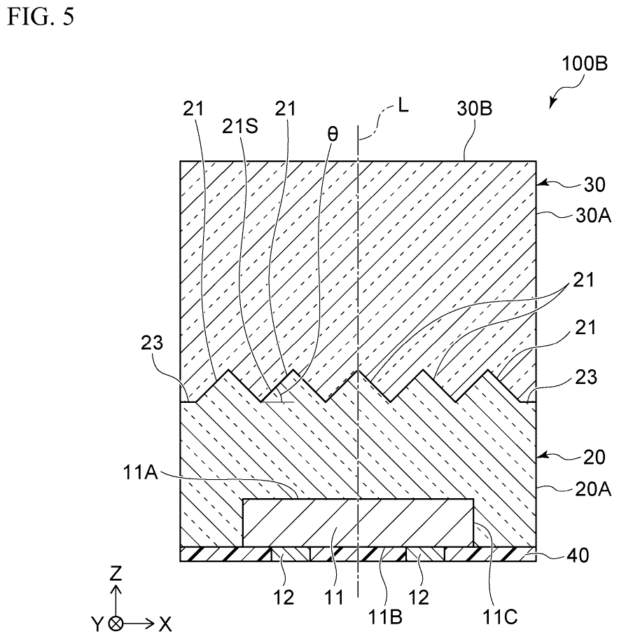

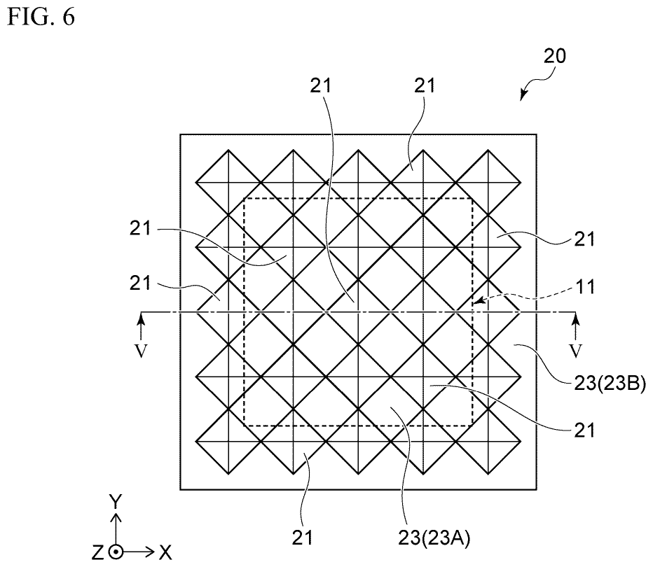

FIG. 5 is a schematic cross-sectional view of a light-emitting device 100B according to a second modification of the embodiment. FIG. 6 is a schematic top view of the light-transmissive member 20 in the light-emitting device 100B according to the second modification. The cross section of the light-transmissive member 20 illustrated in FIG. 5 is a cross section taken along the line V-V in FIG. 6.

In the light-emitting device 100B according to the second modification, the shape of the first protruding portion 21 is a square pyramid. The shape of the first protruding portion 21 in a cross-sectional view is a triangle. In the example illustrated in FIG. 6, the plurality of first protruding portions 21 is arranged side by side in the first direction X and the second direction Y. In addition, the sides of the rectangle that defines the outer shape of the square pyramid in a top view of the first protruding portion 21 are inclined with respect to the sides of the rectangle that is the shape of the light-transmissive member 20 in a top view. For example, the first protruding portion 21 has two sides parallel to one of two diagonal lines of the rectangle of the light-transmissive member 20 in a top view, and two sides parallel to the other diagonal line.

The first protruding portion 21 has two sides parallel to one of two diagonal lines of the rectangle of the light-transmissive member 20 in a top view, and two sides parallel to the other diagonal line, so that light emitted by the light-emitting element 11 can be refracted in a wide-angle direction with respect to the optical axis L at the interface between the light-transmissive member 20 and the light diffusion member 30 in a line B-B direction illustrated in FIG. 1. Accordingly, the amount of light emitted from the lateral surface of the light diffusion member 30 can be increased in the B-B line direction of the light-emitting device 100B. Furthermore, as compared with the light-emitting device of Reference Example 1, the light-emitting device 100B can reduce the difference between the luminous intensity in the direction (line B-B direction illustrated in FIG. 1) passing through the center of the light-emitting device in a top view and toward the corners of the light-emitting device, and the luminous intensity in the direction (line A-A direction and line C-C direction illustrated in FIG. 1) passing through the center of the light-emitting device in a top view and orthogonal to the lateral surfaces of the light-emitting device, and can thus reduce luminous intensity unevenness.

In the example illustrated in FIG. 6, the upper surface of the light-transmissive member 20 includes the flat portion 23 in a region other than the first protruding portions 21. The flat portion 23 includes the outer flat portion 23B surrounding the first protruding portions 21 arranged at the outermost periphery among the plurality of first protruding portions 21 in a top view. In addition, the flat portion 23 includes the inner flat portion 23A located between the first protruding portions 21 adjacent to each other in a direction inclined with respect to the first direction X and the second direction Y.

In the light-emitting device 100B, the upper surface of the light-transmissive member 20 is not limited to including the first protruding portion 21 having a square pyramid shape. That is, the first protruding portion 21 having a square pyramid shape and the first recessed portion having a square pyramid shape may be provided. In addition, the sides of the rectangle that defines the outer shape of the square pyramid in a top view of the first protruding portion 21 are not limited to being inclined with respect to the sides of the rectangle that is the shape of the light-transmissive member 20 in a top view. That is, the sides of the rectangle that defines the outer shape of the square pyramid of the first protruding portion 21 in a top view may be parallel to the sides of the rectangle of the light-transmissive member 20 in a top view.

In the example illustrated in FIGS. 2 to 6, the upper surface of the light-transmissive member 20 has the plurality of first protruding portions 21. The maximum height h of each of the first protruding portions 21 is equal.

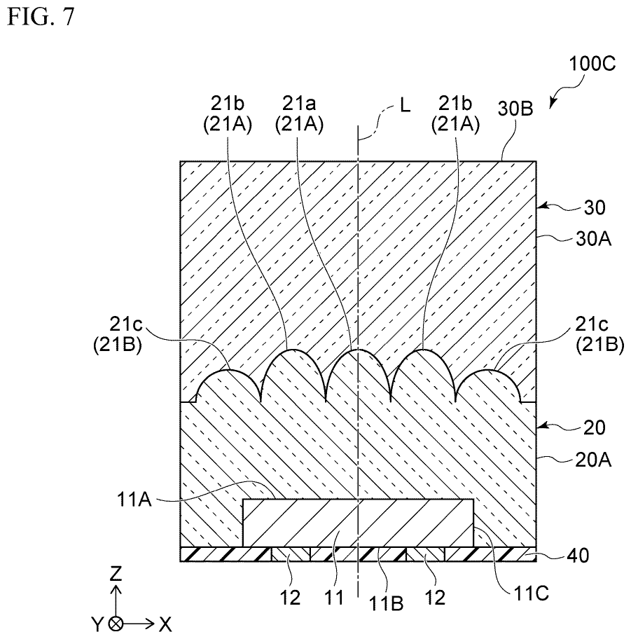

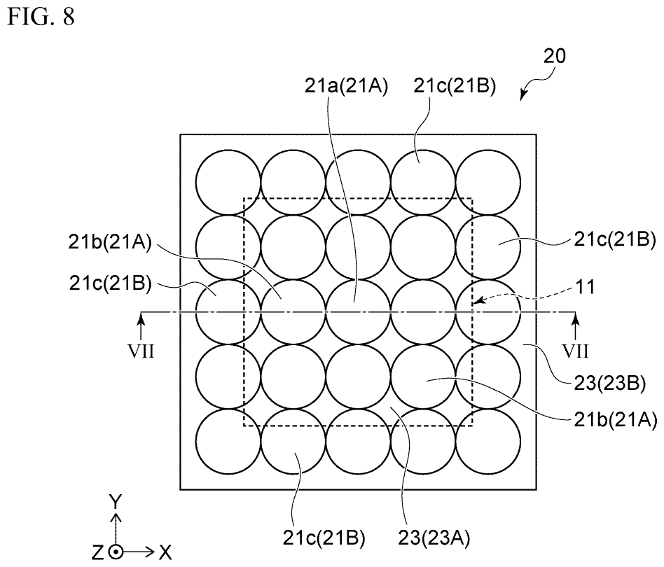

A light-emitting device 100C according to a third modification of the embodiment will be described with reference to FIGS. 7 and 8. The cross section of the light-transmissive member 20 illustrated in FIG. 7 is a cross section taken along the line VII-VII of FIG. 8.

Similarly to the light-emitting device 100, the light-emitting device 100C according to the third modification includes the plurality of first protruding portions 21. As illustrated in FIGS. 7 and 8, the plurality of first protruding portions 21 includes first central protruding portions 21A located in the central portion of the upper surface of the light-transmissive member 20 and first outer protruding portions 21B located outside the first central protruding portions 21A in a top view. The maximum height of the first central protruding portion 21A is higher than the maximum height of the first outer protruding portion 21B. This can reduce that light refracted at the first central protruding portions 21A and traveling toward the lateral surface 30A of the light diffusion member 30 is incident on the first outer protruding portions 21B and refracted at the first outer protruding portions 21B. This can reduce the amount of light that travels toward the upper surface 30B of the light diffusion member 30.

In the example illustrated in FIG. 7, the first central protruding portions 21A are constituted by a first protruding portion 21a located on the optical axis L and first protruding portions 21b respectively located on both sides of the first protruding portion 21a, and the first outer protruding portions 21B are constituted by first protruding portions 21c respectively located on both sides of the first central protruding portions 21A. When the first central protruding portions 21A are constituted by the first protruding portion 21a and the first protruding portions 21b, the maximum height of the first protruding portion 21a may be greater than or equal to the maximum height of the first protruding portions 21b. The first central protruding portions 21A are not limited to being constituted by the first protruding portion 21a and the first protruding portions 21b. That is, a first central protruding portion 21A may be constituted by one first protruding portion 21a. In this case, the first outer protruding portions 21B are constituted by the first protruding portions 21b and the first protruding portions 21c.

The plurality of first protruding portions 21 may be arranged concentrically to or radially from the center of the upper surface 11A of the light-emitting element 11 in a top view.

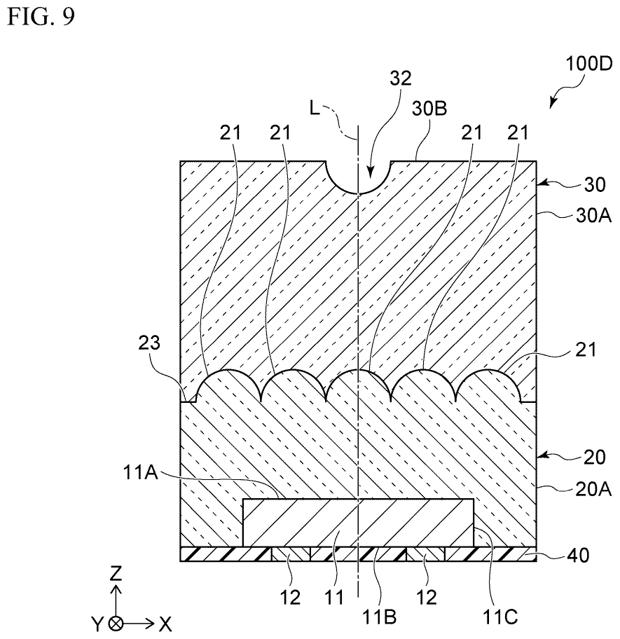

A light-emitting device 100D according to a fourth modification of the embodiment will be described with reference to FIG. 9. In the light-emitting device 100D according to the fourth modification, the upper surface 30B of the light diffusion member 30 includes a second recessed portion 32. The surface of the second recessed portion 32 is in contact with air, and light traveling in the light diffusion member 30 is likely to be totally reflected at the interface between the second recessed portion 32 and the air. Thus, the light refracted by the first protruding portions 21 and traveling toward the upper surface 30B of the light diffusion member 30 can be directed toward the lateral surface 30A side by reflection at the interface between the second recessed portion 32 and the air.

For example, the shape of the second recessed portion 32 is a shape obtained by inverting the shape of the first protruding portion 21 in the third direction Z. The second recessed portion 32 is located at a position overlapping the first protruding portion 21 in a top view. The second recessed portion 32 overlaps the center of the upper surface 11A of the light-emitting element 11 in a top view.

In the example illustrated in FIG. 9, the upper surface 30B of the light diffusion member 30 includes the second recessed portion 32 and a flat portion. The surface of the second recessed portion 32 is located lower than the flat portion in the third direction Z.

Each of the light-emitting devices 100 and 100A to 100D includes one light-emitting element 11. However, there is no limitation thereto, and each of the light-emitting devices 100 and 100A to 100D may include a plurality of light-emitting elements 11. In this case, it is preferable that the center of each of the first protruding portions 21 be positioned to overlap the center of the upper surface 11A of a corresponding one of the plurality of light-emitting elements 11 in a top view. With this configuration, the light emitted from and directed directly above the upper surface 11A of each of the light-emitting elements 11 can be refracted laterally by the first protruding portion 21.

In each of the light-emitting devices 100 and 100A to 100D, the light-emitting element 11 may be disposed on a substrate having a wiring layer, and the element electrode disposed on the upper surface 11A side of the light-emitting element 11 can be electrically connected to the wiring layer of the substrate by wires, for example.

### Method for Manufacturing Light-Emitting Device

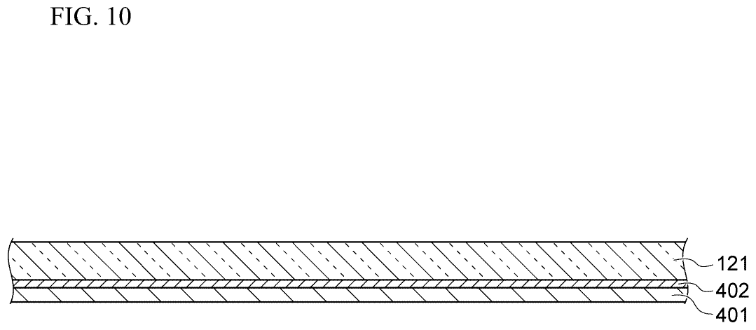

A method for manufacturing the light-emitting device 100 according to the embodiment will be described with reference to FIGS. 10 to 21D.

### Step of Providing First Structure

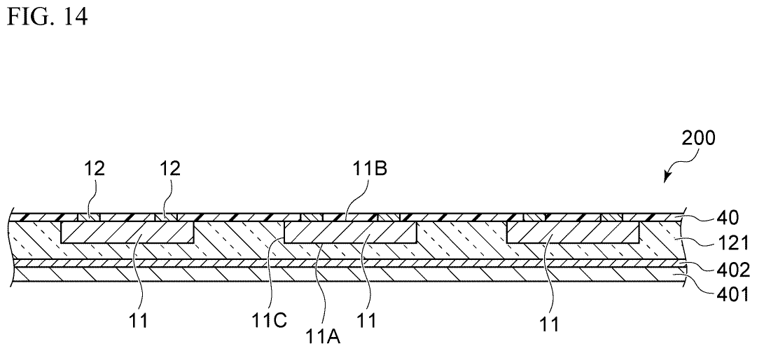

The method for manufacturing the light-emitting device 100 according to the embodiment includes a step of providing a first structure 200 illustrated in FIG. 14. The first structure 200 includes the plurality of light-emitting elements 11 and a first light-transmissive member 121 covering the upper surfaces 11A (surfaces facing a support member 401 in FIG. 14) and the lateral surfaces 11C of the light-emitting elements 11.

The first structure 200 can be provided by the steps illustrated in FIGS. 10 to 14, for example.

As illustrated in FIG. 10, the first light-transmissive member 121 is provided. For example, the sheet-like first light-transmissive member 121 is formed by a coating device. The first light-transmissive member 121 is supported on the support member 401 via, for example, an adhesive member 402. The support member 401 is a metal plate formed of stainless steel or the like.

The first light-transmissive member 121 becomes a part of the light-transmissive member 20 of the above-described light-emitting device 100 through a process described below. Therefore, the first light-transmissive member 121 includes a first base material and a wavelength conversion material. The first base material is, for example, a silicone resin which is a thermosetting resin. In the step of providing the first light-transmissive member 121 illustrated in FIG. 10, the resin of the first base material of the first light-transmissive member 121 is in the uncured state. The resin of the first base material of the first light-transmissive member 121 is in a state of Stage B, for example. Alternatively, in the step of providing the first light-transmissive member 121, the resin of the first base material of the first light-transmissive member 121 may be in a state of Stage A.

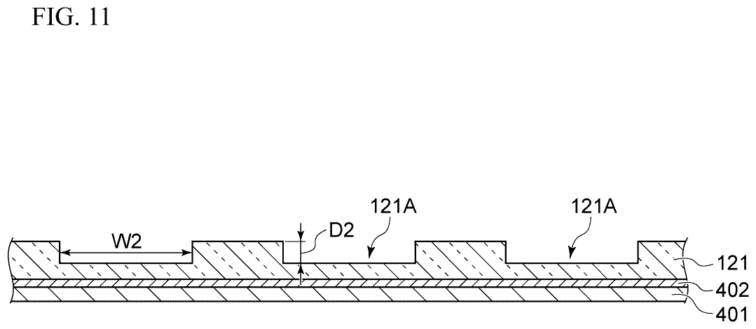

After the sheet-like first light-transmissive member 121 is provided, a plurality of recessed portions 121A are formed in the first light-transmissive member 121 as illustrated in FIG. 11. The recessed portion 121A can be formed by, for example, pressing a mold from the upper surface of the first light-transmissive member 121 (i.e., the surface of the first light-transmissive member 121 opposite to the surface facing the adhesive member 402) to a predetermined depth. The recessed portion 121A does not pass through the first light-transmissive member 121. A depth D2 of the recessed portion 121A illustrated in FIG. 11 may be, for example, a distance D1 from the upper surface 11A to the lower surface 11B of the light-emitting element 11 in the third direction Z illustrated in FIG. 2. A width W2 of the recessed portion 121A illustrated in FIG. 11 may be equal to or greater than a distance W1 of the light-emitting element 11 in the first direction X illustrated in FIG. 2.

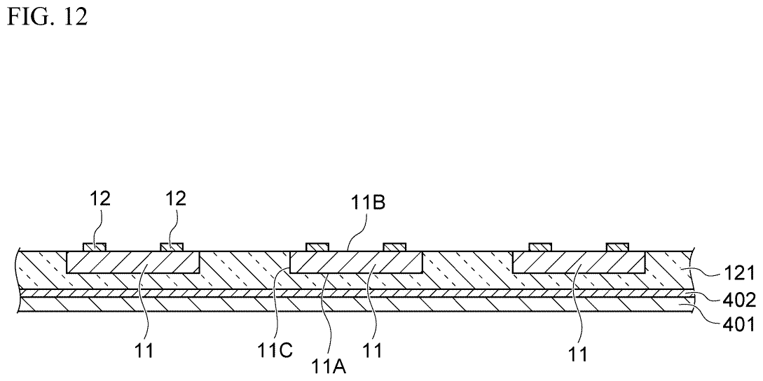

After the plurality of recessed portions 121A are formed in the first light-transmissive member 121, as illustrated in FIG. 12, the light-emitting element 11 is disposed in each of the plurality of recessed portions 121A, and the first light-transmissive member 121 is heated to cure the resin of the first base material to Stage C. The resin of the first base material of the first light-transmissive member 121 is cured to Stage C after disposing the light-emitting elements 11 in the recessed portions 121A, so that misalignment of the light-emitting element 11 relative to the first light-transmissive member 121 can be reduced.

In the step of disposing the light-emitting elements 11 in the recessed portions 121A of the first light-transmissive member 121, the upper surface 11A of the light-emitting element 11 faces the bottom surface that defines the recessed portion 121A. At this time, the surface of the light-emitting element 11 on which the electrodes 12 are disposed is exposed from the first light-transmissive member 121. In the step of disposing the light-emitting elements 11 in the recessed portions 121A, the electrodes 12 are disposed on the lower surface 11B of the light-emitting element 11. The lower surface 11B of the light-emitting element 11 and the electrodes 12 are exposed from the first light-transmissive member 121.

In the step of curing the resin of the first base material of the first light-transmissive member 121 to Stage C, for example, the heating temperature is about 150° C. and the heating time is about 6 hours.

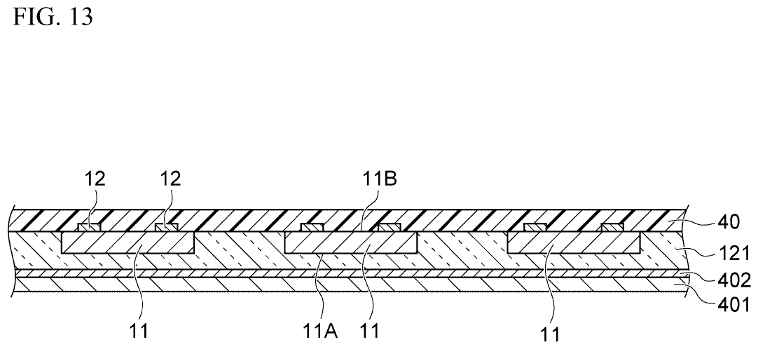

After the resin of the first base material of the first light-transmissive member 121 is cured to Stage C, as illustrated in FIG. 13, the light reflective member 40 is formed on the lower surfaces 11B of the light-emitting elements 11 so as to cover the electrodes 12. Examples of a method for forming the light reflective member 40 include compression molding. Thereafter, the surface of the light reflective member 40 is ground, so that as illustrated in FIG. 14, the surface of the electrodes 12 located on an opposite side to the light-emitting element 11 is exposed from the light reflective member 40. The first structure 200 is provided by the steps described above. The formation of the electrodes 12 and the light reflective member 40 may be omitted.

### Step of Providing Second Structure

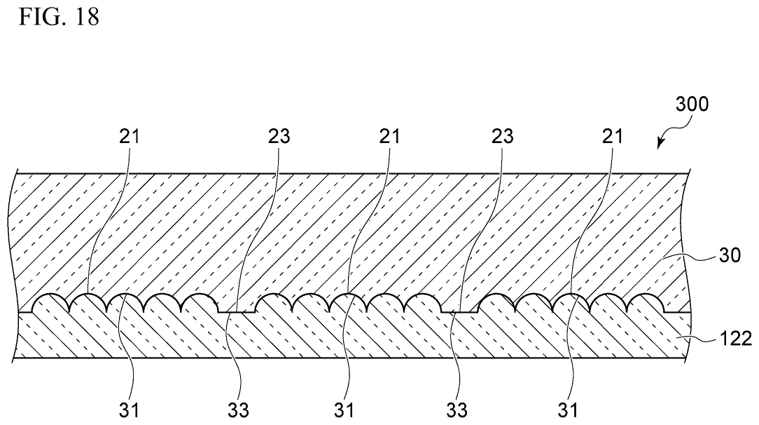

The method for manufacturing the light-emitting device 100 according to the embodiment includes a step of providing a second structure 300 illustrated in FIG. 18. The second structure 300 includes a second light-transmissive member 122 and the light diffusion member 30 disposed on an upper surface of the second light-transmissive member 122. The second light-transmissive member 122 together with the first light-transmissive member 121 described above constitute the light-transmissive member 20 of the light-emitting device 100.

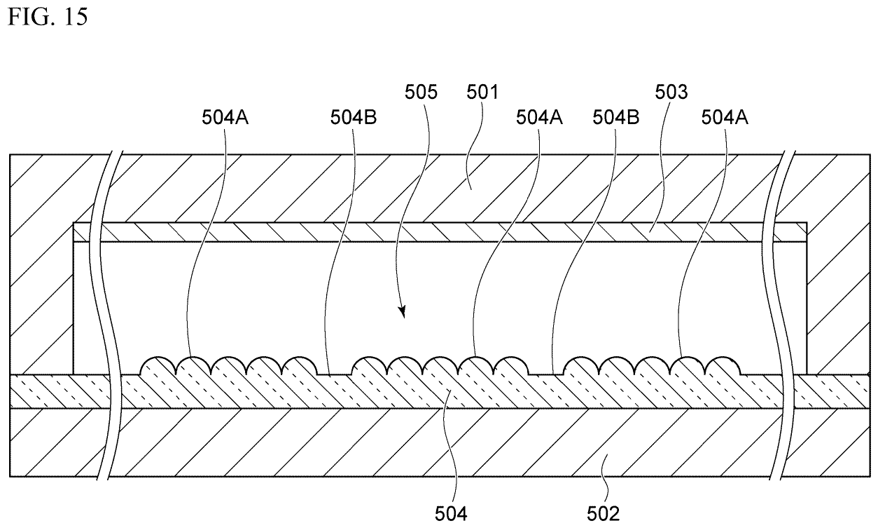

The second structure 300 can be provided by the steps illustrated in FIGS. 15 to 18, for example.

The step of providing the second structure 300 includes a step of preparing an upper mold 501, a transfer sheet 504, and a lower mold 502 illustrated in FIG. 15. The upper surface of the lower mold 502 is a flat surface, and the transfer sheet 504 is disposed on the upper surface of the lower mold 502. A space 505 is defined by the upper mold 501 and the transfer sheet 504. If necessary, a release sheet 503 can be disposed on a surface of the upper mold 501 facing the transfer sheet 504 across the space 505. In the example illustrated in FIG. 15, a plurality of fourth protruding portions 504A and a flat portion 504B located between the plurality of fourth protruding portions 504A are arranged on the upper surface of the transfer sheet 504 in contact with the space 505.

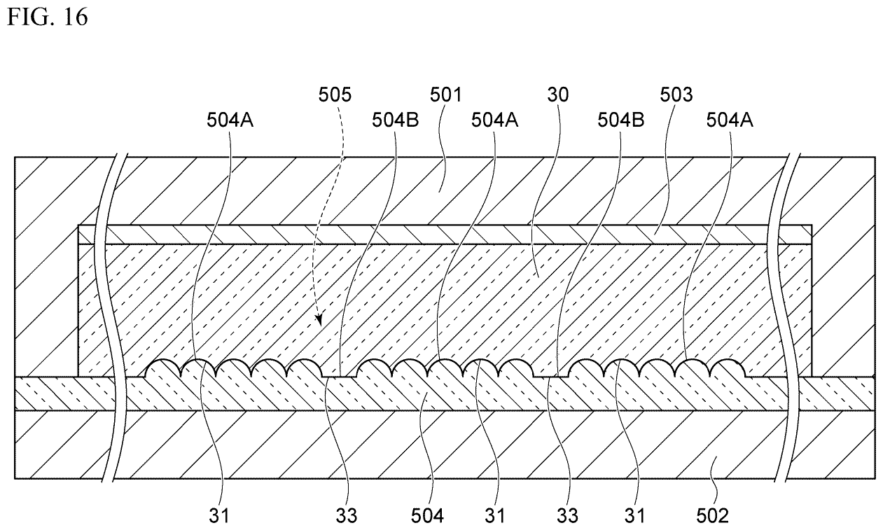

In the space 505 between the upper mold 501 and the transfer sheet 504, a mixture of the light reflective material and resin in an unreacted state, which is a material of the second base material of the light diffusion member 30, is supplied and compression-molded in the space 505. Thus, as illustrated in FIG. 16, a plurality of third recessed portions 31 obtained by inverting the shape of the fourth protruding portions 504A of the transfer sheet 504 are formed on the surface of the light diffusion member 30 facing the transfer sheet 504. In addition, a flat portion 33 is formed on the surface of the light diffusion member 30 facing the transfer sheet 504 at a position in contact with the flat portion 504B of the transfer sheet 504. In addition, the surface of the light diffusion member 30 located on an opposite side to the surface in which the third recessed portions 31 and the flat portion 33 are formed is configured by only a flat surface. Hereinafter, the surface of the light diffusion member 30 in which the third recessed portions 31 are formed may be referred to as a lower surface of the light diffusion member 30. The surface of the light diffusion member 30 opposite to the surface in which the third recessed portions 31 are formed may be referred to as an upper surface of the light diffusion member 30.

In the space 505, the second base material of the light diffusion member 30 is cured to Stage C. For example, the second base material is first cured to Stage B at a heating temperature of about 125° C., for a heating time of about 50 seconds, and with a mold clamping force of about 700 kN. Thereafter, a heat treatment at about 150° C. is performed on the second base material to be cured to Stage C.

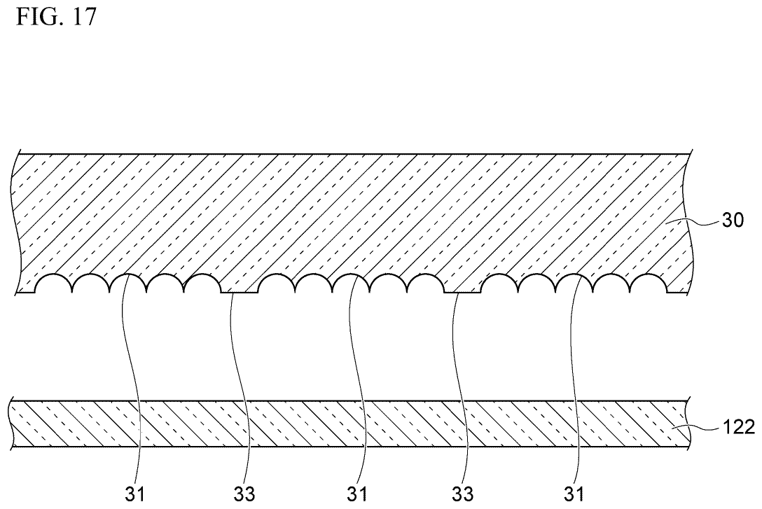

After the light diffusion member 30 including the third recessed portions 31 on the lower surface is formed, the second light-transmissive member 122 in the uncured state (Stage A) is opposed to the lower surface of the light diffusion member 30 as illustrated in FIG. 17, and the second light-transmissive member 122 in the uncured state is disposed on the lower surface of the light diffusion member 30 as illustrated in FIG. 18.

The upper surface of the second light-transmissive member 122 in the uncured state is in contact with the lower surface of the light diffusion member 30, and the first protruding portions 21 in contact with the third recessed portions 31 of the light diffusion member 30 are formed on the upper surface of the second light-transmissive member 122. The flat portion 23 in contact with the flat portion 33 of the light diffusion member 30 is formed on the upper surface of the second light-transmissive member 122. In the second structure 300, the upper surface of the second light-transmissive member 122 includes the first protruding portions 21 and the flat portion 23, and the light diffusion member 30 is in contact with the surface of the first protruding portions 21 and the surface of the flat portion 23.

The second structure 300 can be provided by the steps described above. In the second structure 300, the light diffusion member 30 is in the cured state (Stage C), and the second light-transmissive member 122 is in the uncured state. In the second structure 300, the second light-transmissive member 122 in the uncured state is not limited to being in Stage A, and may be in Stage B.

In the step of providing the second structure 300, the transfer sheet 504 can include fourth protruding portions and fourth recessed portions. In this case, third recessed portions obtained by inverting the shape of the fourth protruding portions are formed on the lower surface of the light diffusion member 30, and first protruding portions obtained by inverting the shape of the third recessed portions are formed on the upper surface of the second light-transmissive member 122. Furthermore, third protruding portions obtained by inverting the shape of the fourth recessed portions are formed on the lower surface of the light diffusion member 30, and the first recessed portions obtained by inverting the shape of the third protruding portions are formed on the upper surface of the second light-transmissive member 122.

In the step of providing the second structure 300, the upper surface of the lower mold 502 is not limited to a flat surface, and the upper surface of the lower mold 502 may include the fourth protruding portions. When the lower mold 502 includes the fourth protruding portions on the upper surface of the lower mold 502, the transfer sheet 504 may be omitted. In addition, the third recessed portions and/or the third protruding portions may be formed on the lower surface of the light diffusion member 30 by laser processing or etching processing without using a mold.

### Step of Forming Third Structure

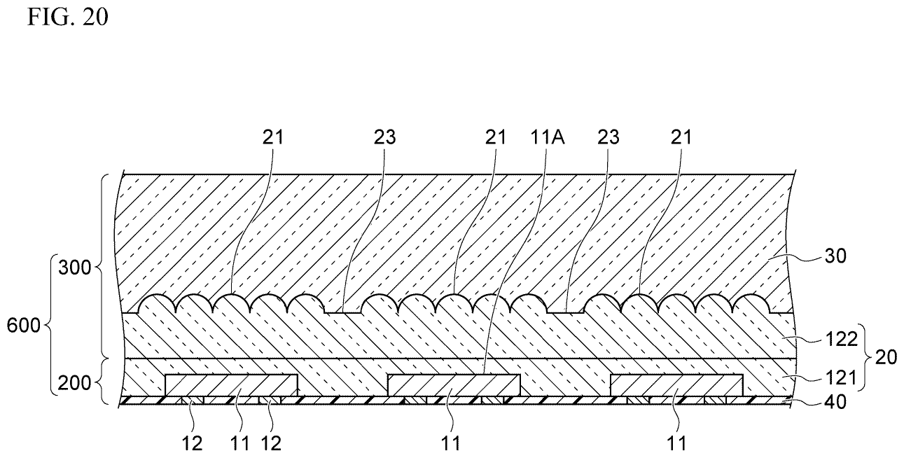

The method for manufacturing the light-emitting device 100 according to the embodiment includes a step of forming a third structure 600 illustrated in FIG. 20.

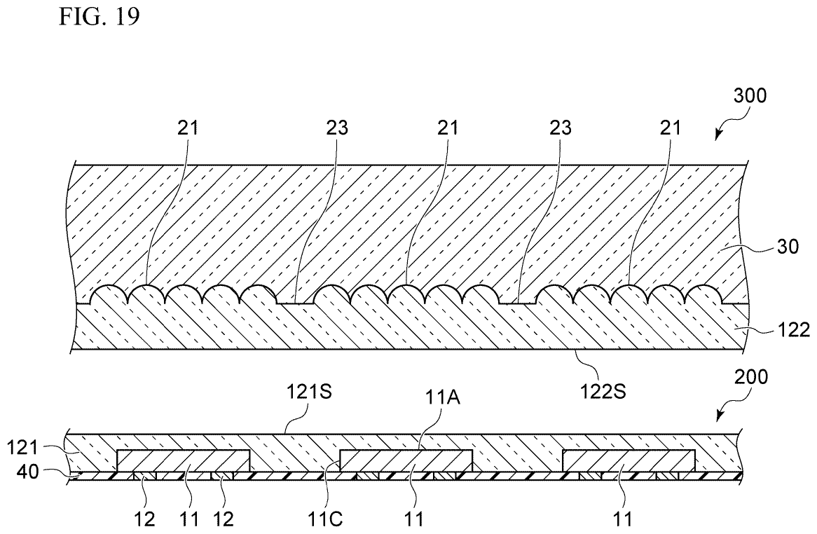

As illustrated in FIGS. 19 and 20, the third structure 600 is formed by overlapping the first structure 200 and the second structure 300 so that the first light-transmissive member 121 in the cured state of the first structure 200 faces the second light-transmissive member 122 in the uncured state of the second structure 300, and curing the second light-transmissive member 122 to Stage C. After a surface 121S of the first light-transmissive member 121 facing the second structure 300, and a surface 122S of the second light-transmissive member 122 facing the first structure 200 are overlapped each other, for example, heating is performed at a temperature of about 150° C. for about 6 hours to cure the second light-transmissive member 122 to Stage C. The first light-transmissive member 121 and the second light-transmissive member 122 are bonded to each other to form the integrated light-transmissive member 20.

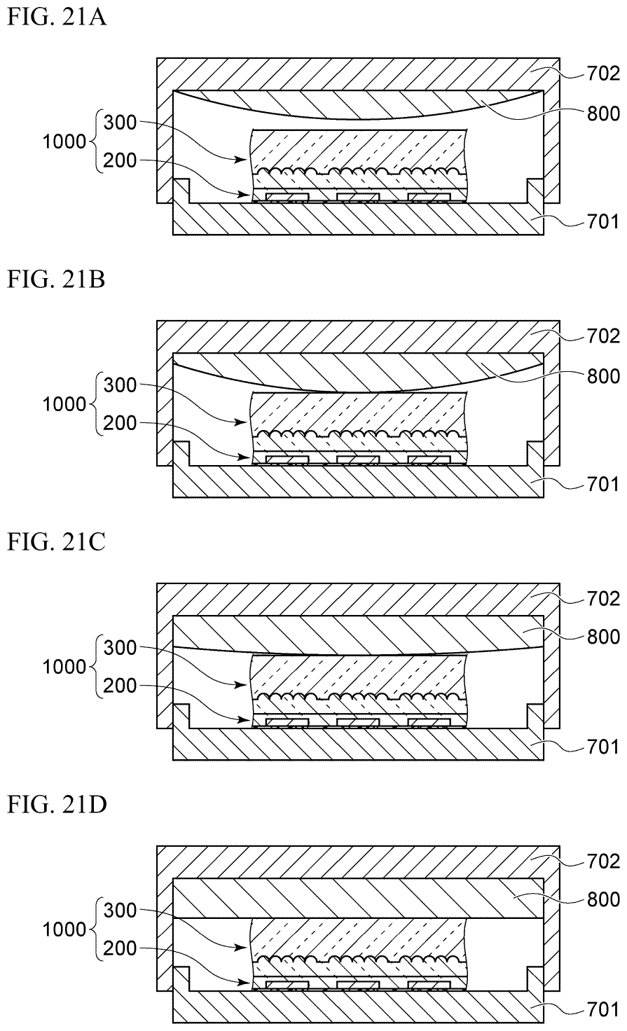

In the step of forming the third structure 600, after the first structure 200 and the second structure 300 are overlapped each other, a pressing force can be applied to the first structure 200 and the second structure 300 before heating. For example, as illustrated in the example of FIG. 21A, a structure 1000 in which the first structure 200 and the second structure 300 are overlapped each other is disposed in a lower mold 701, and an upper mold 702 having a pressing mechanism 800 on the lower surface thereof is disposed above the structure 1000. For example, silicone rubber can be used for the pressing mechanism 800. Thereafter, as illustrated in the example from FIGS. 21B to 21D, the pressing mechanism 800 is inflated so that the pressing mechanism 800 presses the structure 1000. The range on which the pressing force acts is spread from the center of the structure 1000 toward the outer peripheral portion in a top view. This can make it difficult for air bubbles to enter the bonding surface between the first light-transmissive member 121 and the second light-transmissive member 122 as compared with a case in which the range on which the pressing force acts is spread from the outer peripheral portion toward the center of the structure 1000 in a top view.

In the example illustrated in FIG. 21A, the structure 1000 is disposed in the lower mold 701 so that the first structure 200 faces the lower mold 701. In this case, the second structure 300 is pressed by the pressing mechanism 800. However, there is no limitation thereto, and the structure 1000 may be disposed in the lower mold 701 such that the second structure 300 faces the lower mold 701. In this case, the first structure 200 is pressed by the pressing mechanism 800.

The pressing mechanism 800 can be disposed on the upper surface of the lower mold 701 in addition to the lower surface of the upper mold 702. Thus, the structure 1000 is pressed from both the first structure 200 side and the second structure 300 side by the two pressing mechanisms 800.

For example, as Reference Example 2, a manufacturing method is conceivable in which the light-transmissive member 20 is formed so as to cover the plurality of light-emitting elements 11 to provide a structure on the light-emitting element side, and the light diffusion member 30 is bonded to the upper surface of the light-transmissive member 20 of the structure to form the third structure 600. On the other hand, the present embodiment employs a method of forming the third structure 600 by bonding the first light-transmissive member 121 of the first structure 200 and the second light-transmissive member 122 of the second structure 300. According to the present embodiment, the force applied to the light-emitting element 11 at the time of bonding can be reduced and damage to the light-emitting element 11 can be reduced as compared with Reference Example 2. Thus, reliability of the light-emitting device 100 can be improved.

In addition, in the manufacturing method of Reference Example 2, because the light-transmissive member 20 having a thickness greater than the thickness of each of the first light-transmissive member 121 and the second light-transmissive member 122 is heated and cured, heat may not be transmitted to the center of the light-transmissive member 20 in a thickness direction, and curing unevenness may occur. On the other hand, in the present embodiment, the first light-transmissive member 121 and the second light-transmissive member 122 are individually heated and cured. Therefore, each of the first light-transmissive member 121 and the second light-transmissive member 122 is heated and cured in a state of being thinner than the light-transmissive member 20. As a result, curing unevenness of the first light-transmissive member 121 and the second light-transmissive member 122 can be reduced, and reliability of the light-emitting device 100 can be improved.

The case has been described above in which, in the step of bonding the first light-transmissive member 121 and the second light-transmissive member 122 to each other, the first light-transmissive member 121 is in the cured state and the second light-transmissive member 122 is in the uncured state. However, there is no limitation thereto, and in the step of bonding the first light-transmissive member 121 and the second light-transmissive member 122, the first light-transmissive member 121 may be in the uncured state, and the second light-transmissive member 122 may be in the cured state.

In the step of bonding the first light-transmissive member 121 and the second light-transmissive member 122 to each other, one of the first light-transmissive member 121 and the second light-transmissive member 122 is not necessarily in the uncured state. That is, in the step of bonding the first light-transmissive member 121 and the second light-transmissive member 122, both the first light-transmissive member 121 and the second light-transmissive member 122 may be in the uncured state. In a case in which one of the first light-transmissive member 121 and the second light-transmissive member 122 is in the uncured state, misalignment between the first structure 200 and the second structure 300 is less likely to occur and air bubbles can be less likely to enter the bonding surface between the first light-transmissive member 121 and the second light-transmissive member 122 as compared with a case in which both are in the uncured state.

In addition, when the first light-transmissive member 121 covering the plurality of light-emitting elements 11 is in the cured state as in the present embodiment, misalignment of each of the light-emitting elements 11 relative to the first light-transmissive member 121 can be reduced in the first structure 200. Therefore, in the step of bonding the first light-transmissive member 121 and the second light-transmissive member 122, bonding can be performed with high accuracy.

In the step of bonding the first light-transmissive member 121 and the second light-transmissive member 122 to each other, the first light-transmissive member 121 may be in the uncured state and the second light-transmissive member 122 may be in the cured state.

The surface roughness of the surface 121S of the first light-transmissive member 121 of the first structure 200 facing the second structure 300 is preferably less than the surface roughness of the surface 122S of the second light-transmissive member 122 of the second structure 300 facing the first structure 200. The surface 121S of the first light-transmissive member 121 in the cured state is a surface having higher flatness than the surface 122S of the second light-transmissive member 122 in the uncured state, which makes misalignment less likely to occur at the time of bonding the first light-transmissive member 121 and the second light-transmissive member 122 to each other. In addition, the first light-transmissive member 121 and the second light-transmissive member 122 are bonded to each other in such a manner that the surface 122S of the second light-transmissive member 122 in the uncured state follows the surface 121S having high flatness of the first light-transmissive member 121 in the cured state, which can make it difficult for air bubbles to enter the bonding surface between the first light-transmissive member 121 and the second light-transmissive member 122.

In the step of providing the second structure 300, the thickness of the second light-transmissive member 122 is preferably less than the thickness of the light diffusion member 30. Accordingly, the position of the first protruding portions 21 located at the interface between the second light-transmissive member 122 and the light diffusion member 30 can be located closer to the light-emitting element 11, and the refracted light at the first protruding portions 21 can be easily directed to the lateral surface 30A of the light diffusion member 30.

Step of Cutting Third Structure into Plurality of Light-Emitting Devices

The method for manufacturing the light-emitting device 100 according to the embodiment includes a step of, after forming the third structure 600, cutting the third structure 600 into a plurality of light-emitting devices 100.

The third structure 600 is cut at a position where the light-emitting elements 11 are not disposed in a top view, and the third structure 600 is cut into the plurality of light-emitting devices 100. Thus, the light-emitting device 100 illustrated in FIGS. 1 and 2 is obtained. For example, the third structure 600 can be cut using a blade or laser light.

For example, the third structure 600 is cut at the position of the flat portion 23 at the interface between the light diffusion member 30 and the light-transmissive member 20, and the third structure 600 is cut into the plurality of light-emitting devices 100. In this case, it is easy to determine the cutting position.

In addition, the third structure 600 may be cut at the position of the lower end of the first protruding portion 21 to cut the third structure 600 into the plurality of light-emitting devices 100. When the upper surface of the light-transmissive member 20 includes the first recessed portion 22 as illustrated in FIG. 4, the third structure 600 may be cut at the position of the upper end of the first recessed portion 22 to cut the third structure 600 into the plurality of light-emitting devices 100.

When the upper surface 30B of the light diffusion member 30 is a flat surface, it is easy to pick up the light-emitting device 100 by vacuum suction or adsorption of the upper surface 30B of the light diffusion member 30 when transporting the light-emitting device 100 after the cutting.

Embodiments of the present disclosure have been described above with reference to specific examples. However, the present invention is not limited to these specific examples. All aspects that can be practiced by a person skilled in the art modifying the design as appropriate based on the above-described embodiments of the present invention are also included in the scope of the present invention, as long as they encompass the spirit of the present invention. In addition, in the scope of the concepts of the present invention, a person skilled in the art could conceive of various modifications and alterations, and those modifications and alterations will also fall within the scope of the present invention.

What is claimed is:

1. A light-emitting device comprising:
a light-emitting element;
a light-transmissive member disposed on an upper surface and a lateral surface of the light-emitting element; and
a light diffusion member disposed on an upper surface of the light-transmissive member, wherein:
a lateral surface of the light-transmissive member is exposed from the light diffusion member,
a distance between an upper surface of the light-emitting element and an upper surface of the light-transmissive member is greater than a distance between a lateral surface of the light-emitting element and a lateral surface of the light-transmissive member,
an upper surface of the light-transmissive member comprises one or more first protruding portions, and
the light diffusion member is in contact with a surface of the one or more first protruding portions.

2. The light-emitting device according to claim 1, wherein a thickness of the light diffusion member is greater than a thickness of the light-transmissive member.

3. The light-emitting device according to claim 1, wherein a surface of a first protruding portion of the first protruding portions is a curved surface.

4. The light-emitting device according to claim 1, wherein a shape of the first protruding portion is a square pyramid.

5. The light-emitting device according to claim 4, wherein:
a shape of the light-transmissive member in a top view is rectangular, and
a side of a rectangle defining an outer shape of a square pyramid in a top view of the first protruding portion is inclined or parallel to a side of a rectangular shape of the light-transmissive member.

6. The light-emitting device according to claim 1, wherein a center of the first protruding portion overlaps a center of the light-emitting element in a top view.

7. The light-emitting device according to claim 1, wherein, in a cross-sectional view, a maximum width of the first protruding portion is in a range from 1/20 to ⅕ of a width of the light-transmissive member.

8. The light-emitting device according to claim 1, wherein a maximum height of the first protruding portion is in a range from 0.5 times to 2 times of a maximum width of the first protruding portion.

9. The light-emitting device according to claim 1, wherein in a top view, an upper surface of the light diffusion member comprises a second recessed portion at a position overlapping the first protruding portion.

10. The light-emitting device according to claim 1, wherein:
the upper surface of the light-transmissive member comprises a plurality of the first protruding portions,
in a top view, the plurality of the first protruding portions comprise a first central protruding portion located at a central portion of the upper surface of the light-transmissive member, and first outer protruding portions located outside the first central protruding portion, and
a maximum height of the first central protruding portion is greater than a maximum height of the first outer protruding portions.

11. A method for manufacturing a light-emitting device, the method comprising:
providing a first structure comprising:
a plurality of light-emitting elements, and
a first light-transmissive member in a cured state covering upper surfaces and lateral surfaces of the light-emitting elements;
providing a second structure comprising:
a second light-transmissive member in an uncured state, and
a light diffusion member in a cured state disposed on an upper surface of the second light-transmissive member, wherein:
the upper surface of the second light-transmissive member comprises one or more first protruding portions, and
the light diffusion member is in contact with a surface of the one or more first protruding portions;
forming a third structure by overlapping the first structure and the second structure so that the first light-transmissive member of the first structure faces the second light-transmissive member of the second structure, and curing the second light-transmissive member; and
cutting the third structure into a plurality of light-emitting devices by cutting the third structure at a position where the light-emitting elements are not disposed in a top view.

12. The method for manufacturing a light-emitting device according to claim 11, wherein:
the step of providing the second structure comprises:
forming a plurality of third recessed portions and/or third protruding portions on a lower surface of the light diffusion member in an uncured state using a mold,
curing the light diffusion member, and
disposing the second light-transmissive member in an uncured state on the lower surface of the light diffusion member.

13. The method for manufacturing a light-emitting device according to claim 11, wherein, in the step of providing the second structure, a thickness of the second light-transmissive member is less than a thickness of the light diffusion member.

14. The method for manufacturing a light-emitting device according to claim 11, wherein:
the first light-transmissive member of the first structure has a first surface facing the second structure,
the second light-transmissive member of the second structure has a second surface facing the first structure, and
a surface roughness of the first surface is less than a surface roughness of the second surface.

15. The method for manufacturing a light-emitting device according to claim 11, wherein:
in the step of forming the third structure:
after the first structure and the second structure are overlapped, a pressing force is applied to the first structure and the second structure, and
the pressing force is applied so as to spread from a center of the first structure and the second structure toward an outer peripheral portion in a top view.

16. The method for manufacturing a light-emitting device according to claim 11, wherein, in the step of cutting the third structure into the plurality of light-emitting devices, the third structure is cut at a position of a lower end of the first protruding portion.

17. The method for manufacturing a light-emitting device according to claim 11, wherein:
in the step of providing the second structure, the upper surface of the second light-transmissive member comprises a flat portion parallel to the upper surfaces of the light-emitting elements between the first protruding portions adjacent to each other, and
in the step of cutting the third structure into the plurality of light-emitting devices, the third structure is cut at a position of the flat portion.

18. The method for manufacturing a light-emitting device according to claim 11,
wherein, in the step of forming the third structure, the first light-transmissive member of the first structure directly contacts the second light-transmissive member of the second structure.
